(19) United States
(12) Patent Application Publication
(10) Pub. No.: US 2016/0233303 A1
(43) Pub. Date: Aug. 11, 2016

(54) SEMICONDUCTOR STRUCTURE AND MANUFACTURING METHODS THEREOF

(71) Applicant: UNITED MICROELECTRONICS CORP., Hsin-Chu City (TW)

(72) Inventors: Hsin-Yu Chen, Hsinchu County (TW); Hao-Ming Lee, Taichung City (TW); Sheng-Hao Lin, Hsinchu County (TW); Huai-Tzu Chiang, Tainan City (TW)

(21) Appl. No.: 14/640,033

(22) Filed: Mar. 6, 2015

(30) Foreign Application Priority Data
Feb. 6, 2015 (CN) 201510063318.9

(51) Int. Cl. H01L 29/10; H01L 21/84; H01L 21/8234; H01L 29/06; H01L 27/088

(52) U.S. Cl. CPC H01L 29/1037; H01L 29/0673; H01L 27/088; H01L 21/823412; H01L 21/845

(57) ABSTRACT

The present invention provides a semiconductor structure with nanowire structures. The semiconductor structure includes a substrate, more than one first source/drain disposed on the substrate, and at least one first nanowire structure disposed on the first source/drain, wherein each first source/drain and the first nanowire structure are on different levels.

### BACKGROUND OF THE INVENTION

1. Field of the Invention

The present invention relates to semiconductor structure, and in particular, to a semiconductor structure with nanowires.

2. Description of the Prior Art

The fabrication of a nanowire field effect transistor (FET) with a gate dielectric and a gate conductor surrounding the nanowire channel (also known as a gate-all-around nanowire FET) includes suspension of the nanowires. Suspension of the nanowires allows for the gate conductor to cover all surfaces of the nanowires.

The fabrication of a gate-all-around nanowire FET typically includes the following steps: (1) Definition of the nanowires between source and drain regions by patterning a silicon-on-insulator (SOI) layer. (2) Suspension of the nanowires by isotropic etching that undercuts the insulator on which the nanowires are resting. This etching step also undercuts the insulator at the edge of the source and drain region. (3) A blanket and conformal deposition of the gate dielectric and the gate conductor. The gate dielectric and the gate conductor wraps around the suspended nanowires and fills the undercut at the edge of the source and drain regions. (4) Definition of the gate line which includes the etching of the gate line and removal of the gate dielectric and the gate conductor material from all regions outside the gate line, including gate material deposited in the cavities at the edge of the source and drain regions.

### SUMMARY OF THE INVENTION

The present invention provides a semiconductor structure with nanowire structures, comprising a substrate, more than one first source/drain disposed on the substrate, and at least one first nanowire structure disposed on the first source/drain, wherein each first source/drain and the first nanowire structure are on different levels.

The present invention further provides a method for forming a semiconductor structure, comprising: first, a substrate is provided, a plurality of first source/drain (S/D) regions are formed on the substrate, next, a first material layer is formed on the first S/D region, afterwards, the first material layer is patterned, to form a plurality of first nano channel structures, and an anneal process is performed, to transform each first nano channel structure into a first nanowire structure.

The present invention provides a semiconductor structure with nanowire and the manufacturing process thereof. The key feature is using the silicon substrate to replace the SOI substrate as the substrate. The S/D region is formed on the silicon substrate. Afterwards, the nanowire structures are then formed. The nanowire FET can also be formed based on the structure of the present invention. Besides, since the silicon substrate is cheaper than the SOI substrate, the cost can be decreased.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is schematic diagrams showing the semiconductor structure of the first preferred embodiment of the present invention.

FIG. 2 is schematic diagrams showing the semiconductor structure of the first preferred embodiment of the present invention.

FIG. 3 is schematic diagrams showing the semiconductor structure of the first preferred embodiment of the present invention.

FIG. 3A is the top view diagram of FIG. 3.

FIG. 3B shows another embodiment of the semiconductor structure of the present invention.

FIG. 4 is schematic diagrams showing the semiconductor structure of the first preferred embodiment of the present invention.

FIG. 4A is the cross section diagram along the cross section line B-B′ of FIG. 3A.

FIG. 4B is the top view of the semiconductor structure after the gate structure is formed.

FIG. 5 is the semiconductor structure according to the second preferred embodiment of the present invention.

FIG. 5A is the top view diagram of FIG. 5.

FIG. 6 is the semiconductor structure according to the second preferred embodiment of the present invention.

### DETAILED DESCRIPTION

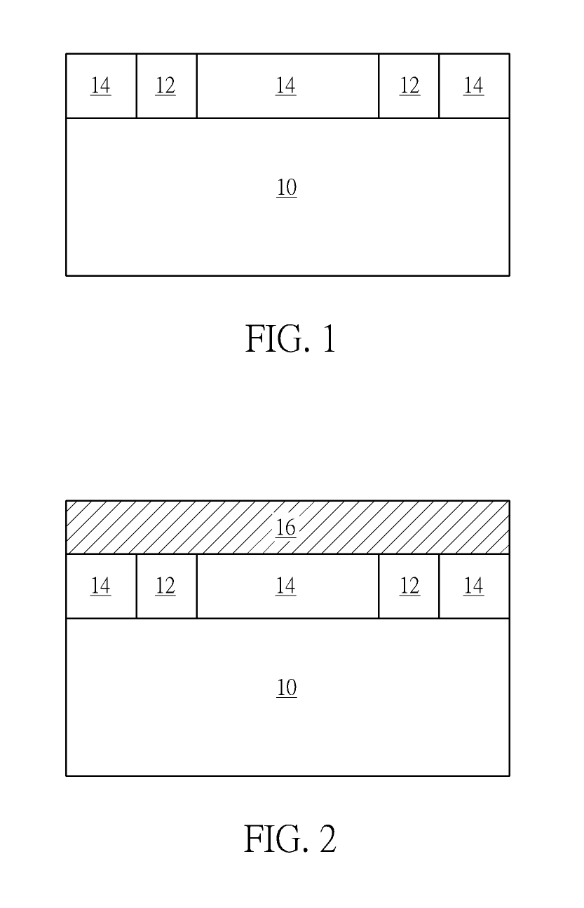

FIGS. 1-4 are schematic diagrams showing the semiconductor structure of the first preferred embodiment of the present invention. As shown in FIG. 1, a substrate 10 is provided, such as a silicon substrate, an epitaxial silicon substrate, a silicon carbide substrate, a silicon germanium substrate or a silicon-on-insulator (SOI) substrate. In this embodiment, the substrate preferably is a silicon substrate, but not limited thereto, and it may comprise a SOI substrate. The substrate 10 has a first conductivity type, or the substrate 10 comprises a first conductivity type well disposed therein. The first conductivity type can be p-type, but is not limited thereto. Next, a plurality of the source/drain (S/D) regions 12 are formed on the substrate, and a dielectric layer 14 is disposed beside the S/D region 12. The dielectric layer 14 may be a silicon dioxide layer, a silicon nitride layer or a silicon oxynitride (SiON) layer. The S/D region 12 can be formed through an ion implantation process, so as to form on the substrate 10, but not limited thereto. The S/D region 12 can also be formed through a selective epitaxial process, and in this case, the material of the S/D region 12 may comprise silicon, germanium, tin germanium, silicon carbide or silicon germanium. The S/D region 12 has a second conductivity type, the second conductivity type and the first conductivity type are complementary to each other. Therefore the second conductivity type is n-type in this embodiment. In addition, after the S/D region 12 is formed, another ion implantation process can be performed, such as an anti-punch through implantation (API), so as to implant the first conductivity type ions into the interface between the S/D region 12 and the substrate 10. For example, by doping the p-type ions, this ensures the S/D region 12 is electrically isolated from the substrate 10, and prevents the signals that would pass through the S/D region 12 to the substrate 10 and influence the performance of the transistors.

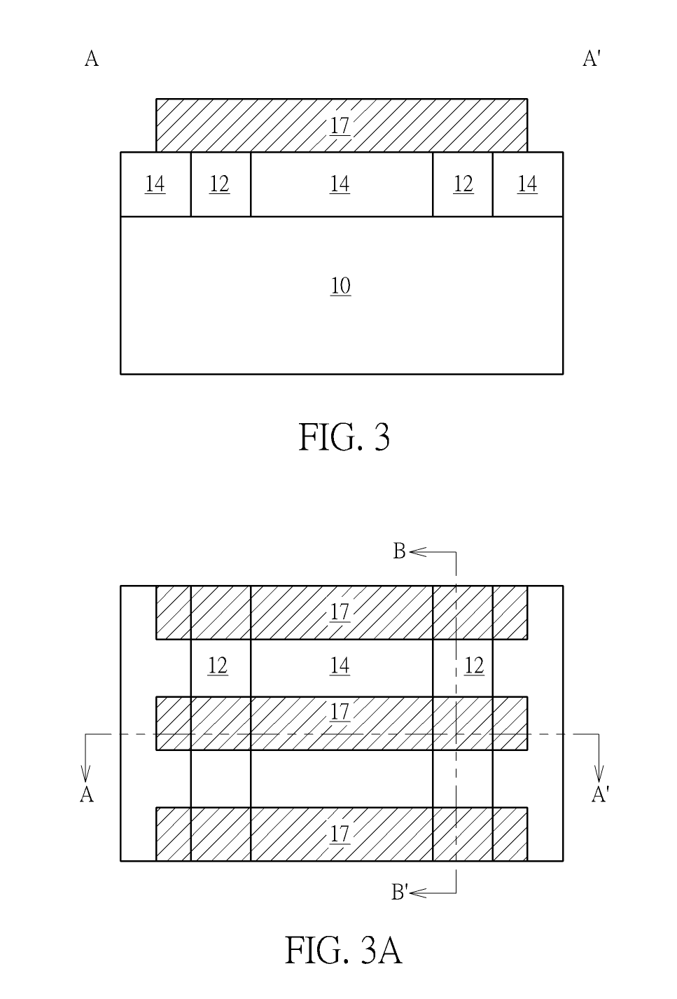

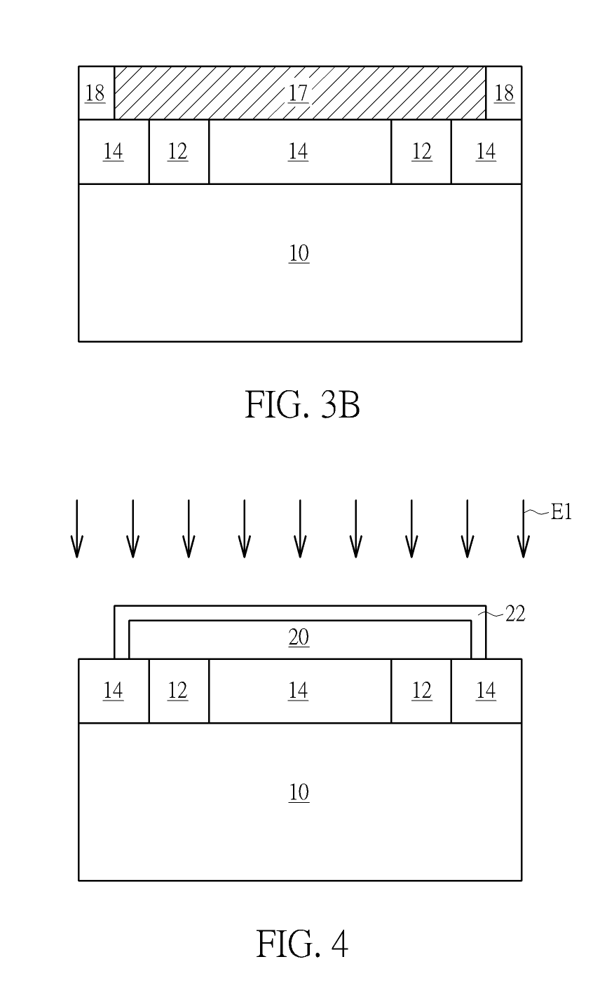

Please refer to FIG. 2, a semiconductor (channel) material layer is formed on the dielectric layer 14 and on the S/D region 12, such as forming a first material layer 16. The first material layer 16 can be formed through a chemical vapor deposition (CVD), but not limited thereto, and it can be also formed through other methods such as sputtering. In addition, the first material layer includes silicon, germanium, tin germanium, silicon carbide or silicon germanium. In this embodiment, the first material layer 16 can be an amorphous material layer or a polycrystalline material layer. Afterwards, as shown in FIG. 3, a patterning process is performed, such as an etching process, to remove parts of the first material layer 16, and the remaining first material layer 16 is defined as at least one first nano channel structure 17. FIG. 3A is the top view diagram of FIG. 3, and FIG. 3 is the cross section diagram along the cross section line A-A′ of FIG. 3. When viewed in top view, a plurality of the first nano channel structures 17 are formed at the same time, and each first nano channel structure 17 and S/D region 12 are arranged along different directions, and contact each other. Preferably, the first nano channel structure 17 and the S/D region 12 are arranged orthogonally. Besides, each first nano channel structure 17 mentioned here will be transformed into a stripe-shaped nanowire structure through an anneal process in the following steps, and the gate structure will be crossed over the nanowire structure so as to form the nanowire FET structure.

In addition, in another embodiment of the present invention, as shown in FIG. 3B, which shows another embodiment of the semiconductor structure of the present invention. After the first nano channel structures 17 are formed, a dielectric layer 18 may be selectively formed on each first nano channel structure 17, and a planarization process is then performed, such as a chemical-mechanical polishing (CMP), so as to obtain a planar surface. The dielectric layer 18 such as silicon oxide or silicon nitride, helps to protect the elements which are disposed under the dielectric layer 18 (such as the nanowire structures formed in the following steps), and this embodiment should be included within the scope of the present invention. To simplify the description, the following paragraph still takes the structure that is shown in FIG. 3 (without forming the dielectric layer 18) as an example.

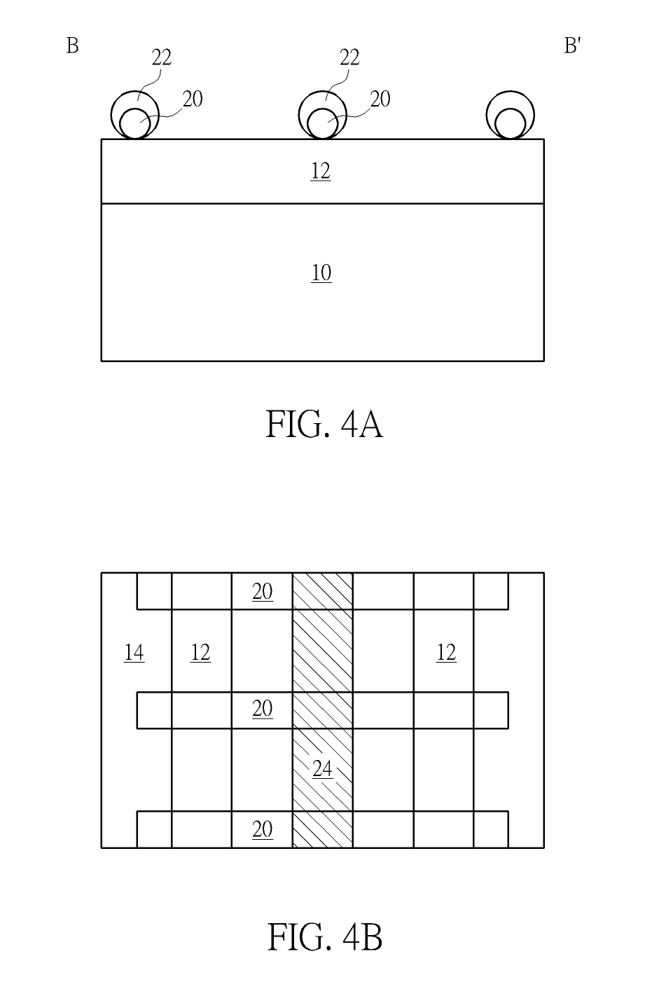

As shown in FIG. 4, an anneal process El is performed, to transform each first nano channel structure 17 into a first nanowire structure 20. More precisely, the anneal process may include a crystallization process and a condensation process, wherein the crystallization process mainly comprises a heating step, helping the amorphous material or the polycrystalline material of the first material layer 16 transform into a single crystalline material. The temperature is about 200° C. to 80020 C., for example. The condensation process may include an oxidation process, to form an oxide layer 22 on the outer surface of the first nanowire structure 20. For example, if the first material layer 16 is a silicon germanium layer, the germanium containing ratio in the center portion of the first nanowire structure 20 is higher than the germanium containing ratio in the oxide layer 22. Besides, after the anneal process E1 is performed, the germanium atoms will gather toward the center of the first nanowire structure 20, and the first nanowire structure 20 preferably has a circular cross section when viewed in a cross section view (please refer to FIG. 4A, which is the cross section diagram along the cross section line B-B′of FIG. 3A). In addition, if the anneal process does not use any oxygen (for example, only using the hydrogen during the process), the oxide layer 22 will not be formed on the outer surface of the first nanowire structure 20.

Afterwards, other semiconductor manufacturing processes can be applied in the first nanowire structure 20, so as to form the nanowire field effect transistor (FET). For example, the oxide layer 22 on the outer surface of the first nanowire structure 20 is removed. Please refer to FIG. 4B, which shows the top view of the semiconductor structure after the gate structure is formed. As shown in FIG. 4B, the gate structure 24 is formed and crosses over each first nanowire structure 20, and is disposed between two S/D regions 12. Preferably, the gate structure 24 and the first nanowire structure 20 are arranged orthogonally, and the gate structure 24 is arranged parallel to the S/D region 12, but not limited thereto. The gate structure 24 may include a gate dielectric layer and a gate conductive layer. Next, the following steps including: filling a dielectric layer (not shown) and forming the contact plugs (not shown) are performed in sequence, so as to form the gate contact plugs and the S/D contact plugs, and the processes mentioned above are well known to those skilled in the art, and are not described redundantly. Furthermore, in one case of the present invention, the gate structure 24 maybe formed directly, to cross over the first nanowire structure 20. Or in another case, after parts of the dielectric layer 14 disposed under the first nanowire structure 20 are removed, and the gate structure is then formed on the outer surface of the first nanowire structure 20, and in this way, the gate structure can be covered on the whole outer surface of the first nanowire structure 20, so as to form the gate-all-around nanowire FET.

In the conventional nanowire FET, the SOI substrate is usually used as the substrate of the nanowire FET since the SOI substrate has an insulating layer disposed thereon. The nanowire can be formed on the insulating layer directly, and the S/D regions are formed through an ion implantation process. Next, the gate structures and the contact plugs are then formed. The insulating layer helps to electrically isolate the substrate from the S/D region. However, the cost of the SOI substrate is higher than other substrates (such as silicon substrate), so the cost of the manufacturing process is increased too. The key feature of the present invention is use the silicon substrate as the substrate, and does not need to use a SOI substrate as the substrate. The S/D region 12 is formed on the silicon substrate, and the first nanowire structure 20 is then formed on the S/D region 12. Therefore, the first nanowire structure 20 crosses on the S/D region 12. In other words, the S/D region 12 and the first nanowire structure 20 are not disposed on a same level, and the first nanowire structure 20 is disposed higher the S/D region 12 is. In addition, since the S/D region 12 contacts the substrate 10 directly, an anti-punch through (API) process can be further performed, to electrically isolate the S/D region 12 from the substrate 10. In the conventional nanowire FET, the S/D region and the nanowire structure are usually disposed on a same level, and there is an insulating layer disposed between the S/D region and the substrate, so the S/D region will not contact the substrate directly. In the present invention, the SOI substrate is replaced by the silicon substrate, and the cost of the process can be decreased.

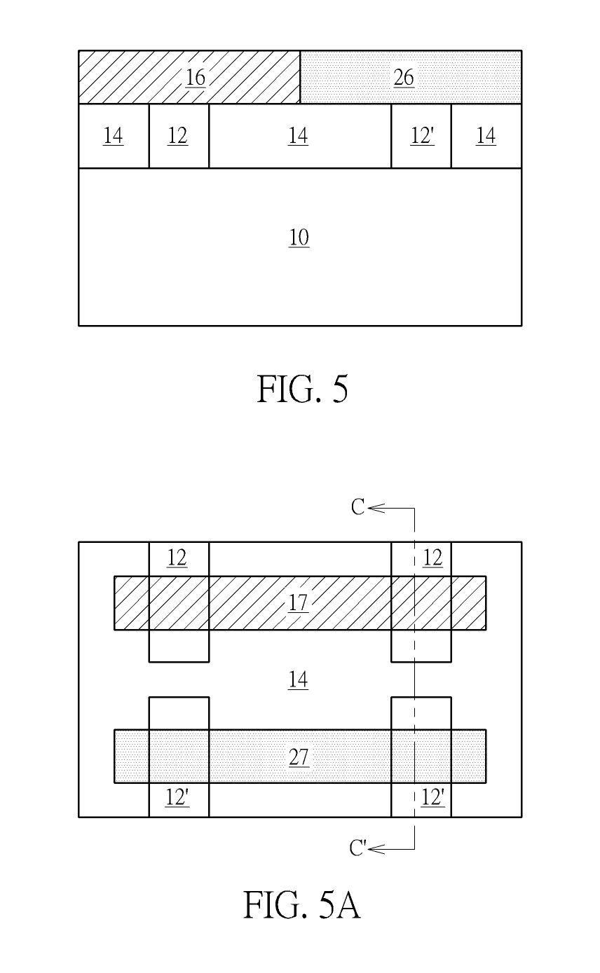

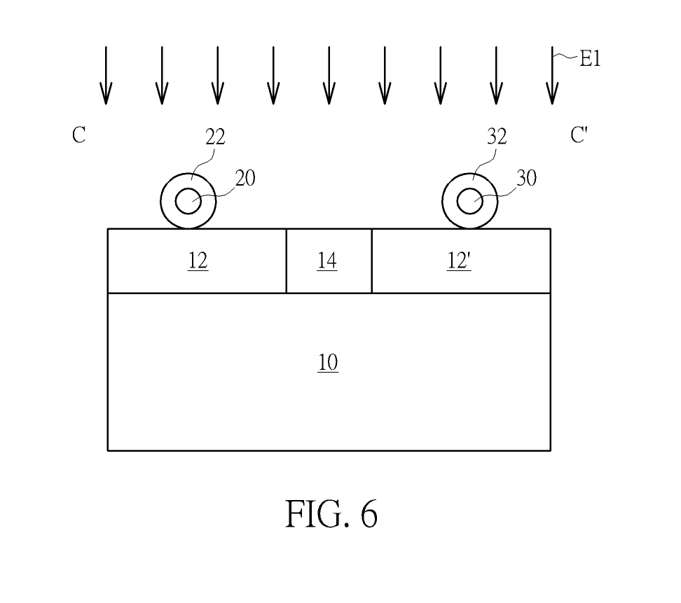

FIGS. 5-6 show the semiconductor structure according to the second preferred embodiment of the present invention. FIG. 5A is the top view diagram of FIG. 5. To simplify the description, the following description will detail the dissimilarities among the different embodiments and the identical features will not be redundantly described. In order to compare the differences between the embodiments easily, the identical components in each of the following embodiments are marked with identical symbols. The difference between this embodiment and the first preferred embodiment is after the S/D region 12 is formed, except for the first material layer 16 then being formed on the S/D region 12, this embodiment further comprises forming a second material layer 26 on the S/D region 12, wherein the second material layer 26 and the first material layer 16 are disposed on a same level, and both of them cross over the S/D region 12. Besides, silicon containing ration and the germanium containing ratio of the second material layer 26 is different from that of the first material layer 16. In other words, both of them include same element (such as silicon and germanium), but the ratio is different. Take the silicon germanium material Si₁₋ₓGeₓ as an example, where x stands for the proportion of germanium in the silicon germanium material. The x of the first material layer is between 20-60%, and preferably between 50-60%, the x of the second material layer is between 20-60%, and preferably between 20-30%. However, in another embodiment of the present invention, the first material layer 16 and the second material layer 26 can be replaced by other suitable semiconductor (channel) materials respectively. Afterwards, a patterning process is then performed, such as an etching process, so as to form a plurality of the first nano channel structures 17 and a plurality of the second nano channel structures 27, wherein each first nano channel structure 17 is disposed on parts of the S/D region 12, and each second nano channel structure 27 is disposed on parts of the S/D region 12′, as shown in FIG. 5A. When viewed in top view, the S/D region 12 and the S/D region 12′ do not contact each other, to avoid different nanowire structures which are formed in the following steps being electrically connected to each other. Besides, the conductivity type of the S/D region 12 may be the same as or complementary to the conductivity of the S/D region 12′.

Next, as shown in FIG. 6, FIG. 6 is the cross section diagram showing the cross section structure along the cross section line C-C′ of FIG. 5A. An anneal process E1 is performed, to transform each first nano channel structure 17 into a first nanowire structure 20, and also to transform each second nano channel structure 27 into a second nanowire structure 30, and the anneal process El is the same as the anneal process mentioned in the first preferred embodiment. The anneal process El is preferably compared with oxygen. Therefore, the first nanowire structure 20 includes a core portion and the oxide layer 22 surrounding outside, and the germanium containing ratio of the core portion of the first nanowire structure 20 is higher than that of the oxide layer 22. Similarly, the second nanowire structure 30 also includes a core portion and the oxide layer 32 surrounding outside, and the germanium containing ratio of the core portion of the second nanowire structure 30 is higher than that of the oxide layer 32. In addition, after the anneal process E1, the first nanowire structure 20 and the second nanowire structure 30 preferably have a circular cross section.

It is noteworthy that since the first nano channel structure 17 and the second nano channel structure 27 have different germanium containing ratios, after the anneal process E1, the first nanowire structure 20 and the second nanowire structure 30 may have different diameters. For example, if one nanowire structure has a higher germanium containing ratio, the nanowire structure will have a larger diameter after the anneal process is performed. Take the silicon germanium material Si₁₋ₓGeₓ as an example, where x stands for the proportion of germanium in the silicon germanium material, if the x of the first material layer 16 is 60% and the x of the second material layer 26 is 30%, the ratio of the first nanowire structure's diameter to the second nanowire structure's diameter is about 60%:30%. Since the diameter of the nanowire structure will influence the threshold voltage (Vt) of a nanowire filed effect transistor (FET) structure, by using the methods mentioned above, at least two nanowire structures with same conductivity type but having different Vt can be formed on one substrate, so as to increase the flexibility of the nanowire FET applications.

In summary, the present invention provides a semiconductor structure with nanowire and the manufacturing process thereof. The key feature is using the silicon substrate to replace the SOI substrate as the substrate. The S/D region is formed on the silicon substrate, and afterwards, the nanowire structures are then formed. The nanowire FET can also be formed based on the structure of the present invention. Besides, since the silicon substrate is cheaper than the SOI substrate, so the cost can be decreased.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor structure, comprising:
a substrate;
a plurality of first source/drain (S/D) regions disposed on the substrate; and
at least one first nanowire structure disposed on each of the plurality of first S/D regions, wherein each first nanowire structure and each of the plurality of first S/D regions are disposed on different levels.

2. The semiconductor structure of claim 1, wherein each of the plurality of first S/D regions contacts the substrate directly.

3. The semiconductor structure of claim 1, further comprising at least second nanowire structure and a plurality of second S/D regions, and the second nanowire structure is disposed on each of the plurality of second S/D regions.

4. The semiconductor structure of claim 3, wherein the diameter of the first nanowire structure is different from the diameter of the second nanowire structure.

5. The semiconductor structure of claim 1, wherein the first nanowire structure comprises silicon, germanium, tin germanium, silicon carbide or silicon germanium.

6. The semiconductor structure of claim 3, wherein the second nanowire structure comprises silicon, germanium, tin germanium, silicon carbide or silicon germanium.

7. A method for forming a semiconductor structure, comprising:
providing a substrate;
forming a plurality of first source/drain (S/D) regions on the substrate;
forming a first material layer on each of the plurality of first S/D regions;
patterning the first material layer, to form a plurality of first nano channel structures; and
performing an anneal process, to transform each first nano channel structure into a first nanowire structure.

8. The method of claim 7, wherein the first material layer comprises an amorphous material layer or a polycrystalline material layer.

9. The method of claim 7, further comprising forming a plurality of second source/drain (S/D) regions and a second material layer, and the second material layer is disposed on parts of each of the plurality of second S/D regions.

10. The method of claim 9, further comprising patterning the second material layer to form a plurality of second channel structures, and performing an anneal process, to transform each second nano channel structure into a second nanowire structure.

11. The method of claim 9, wherein the second material layer comprises an amorphous material layer or a polycrystalline material layer.

12. The method of claim 9, wherein both the first material layer and the second material layer include germanium, and the germanium containing ratio of the first material layer is different from the germanium containing ratio of the second material layer.

13. The method of claim 10, wherein the diameter of the first nanowire structure is different from the diameter of the second nanowire structure.

14. The method of claim 7, wherein the anneal process further comprises a crystallization process and a condensation process.
